(19) United States
(12) Patent Application Publication
(10) Pub. No.: US 2020/0111727 A1
(43) Pub. Date: Apr. 9, 2020

(54) SEMICONDUCTOR DEVICE

(71) Applicant: SUMITOMO ELECTRIC INDUSTRIES, LTD., Osaka (JP)

(72) Inventor: Takashi TSUNO, Hyogo (JP)

(21) Appl. No.: 16/488,665

(22) PCT Filed: Nov. 2, 2017
(86) PCT No.: PCT/JP2017/039806

§ 371 Date: Aug. 26, 2019

(30) Foreign Application Priority Data
Mar. 1, 2017 (JP) 2017-038443

(51) Int. Cl. H01L 23/495; H01L 23/00; H01L 29/78

(52) U.S. Cl. CPC H01L 23/49562; H01L 23/49503; H01L 24/48; H01L 2224/49113; H01L 2224/48247; H01L 2224/48472; H01L 29/7802

(57) ABSTRACT

A packaged semiconductor device includes a substrate including a die pad and a drain terminal extending from the die pad in one direction in a plan view, a gate terminal and a source terminal extending in the one direction on both sides of the drain terminal. A semiconductor chip has a rectangular shape and is disposed on the die pad such that short sides are parallel to the drain terminal and a center of gravity is closer to the source terminal than the gate terminal. A gate pad is disposed on the gate terminal side on an upper surface of the semiconductor chip. A plurality of source pads is arrayed from the source terminal side toward the gate terminal side on the upper surface of the semiconductor chip. A gate wire connects the gate pad to the gate terminal, and a plurality of source wires connects the plurality of source pads to the source terminal.

### TECHNICAL FIELD

The present disclosure relates to a semiconductor device.

The present application is based on and claims priority to Japanese Patent Application No. 2017-038443 filed on Mar. 1, 2017, the entire contents of which are herein incorporated by reference.

### BACKGROUND ART

Patent Document 1 discloses a power semiconductor device in which the aspect length-to-width ratio of the power semiconductor device is made 1.5 or more, the number of wires to draw a main current from the source electrode is 14 or more, and the current direction is dispersed in two different directions.

### Patent Document

Patent Document 1: Japanese Laid-Open Patent Application Publication No. 2006-156479

### SUMMARY OF THE INVENTION

A semiconductor device according to one embodiment of the present disclosure is a packaged semiconductor device that includes a substrate including a die pad and a drain terminal extending from the die pad in one direction in a plan view, a gate terminal and a source terminal extending in the one direction on both sides of the drain terminal. A semiconductor chip has a rectangular shape and is disposed on the die pad such that short sides are parallel to the drain terminal and a center of gravity is closer to the source terminal than the gate terminal. A gate pad is disposed on the gate terminal side on an upper surface of the semiconductor chip. A plurality of source pads is arrayed from the source terminal side toward the gate terminal side on the upper surface of the semiconductor chip. A gate wire connects the gate pad to the gate terminal, and a plurality of source wires connects the plurality of source pads to the source terminal.

### BRIEF DESCRIPTION OF THE DRAWINGS

FIG. 1 is atop view illustrating an example of a semiconductor device according to the present embodiment;

FIG. 2 is across-sectional view illustrating an example of a configuration of a semiconductor chip of a semiconductor device according to the present embodiment;

FIG. 3 is a diagram illustrating a generated back electromotive force when a MOS transistor is switched; and

FIG. 4 is across-sectional view illustrating an example of a connection state between a source terminal and a source pad of a semiconductor device according to the present embodiment.

### MODE OF CARRYING OUT THE INVENTION

Hereinafter, embodiments for carrying out the present disclosure are described below with reference to the drawings.

### Description of Embodiments of the Present Disclosure

First, embodiments of the present disclosure are listed below.

[1] A semiconductor device in accordance with an embodiment of the present disclosure is a packaged semiconductor device including a substrate including a die pad and a drain terminal, the drain terminal extending from the die pad in one direction in a plan view; a gate terminal and a source terminal extending in the one direction on both sides of the drain terminal; a semiconductor chip having a rectangular shape and disposed on the die pad such that short sides are parallel to the drain terminal and a center of gravity is closer to the source terminal than the gate terminal; a gate pad disposed on the gate terminal side on an upper surface of the semiconductor chip; a plurality of source pads arrayed from the source terminal side toward the gate terminal side on the upper surface of the semiconductor chip; a gate wire connecting the gate pad to the gate terminal; and a plurality of source wires connecting the plurality of source pads to the source terminal.

This allows the semiconductor chip to be disposed close to the source terminal to shorten the source wires, thereby reducing the inductance of the source wires. By reducing the inductance of the source wires, the back electromotive force generated between the gate and the source during switching of the semiconductor device can be reduced, thereby enabling faster switching.

[2] At least one of the plurality of source wires is shorter than the gate wire.

[3] Two or more of the plurality of source wires are shorter than the gate wire.

[4] The semiconductor chip is a wide gap semiconductor chip.

### Details of Embodiments of the Present Disclosure

Hereinafter, one embodiment of the present disclosure (hereinafter referred to as “the present embodiment”) is described below in detail, but the present embodiment is not limited thereto.

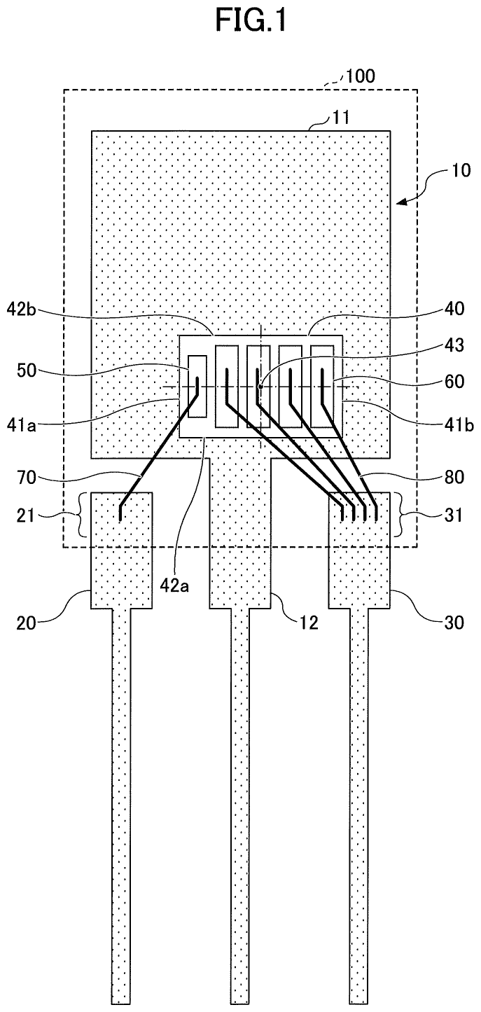

FIG. 1 is a top view illustrating an example of a semiconductor device according to the present embodiment. In FIG. 1, the semiconductor device according to the present embodiment includes a substrate 10, a gate terminal 20, a source terminal 30, a semiconductor chip 40, a gate pad 50, source pads 60, a gate wire 70, source wires 80, and a package 100. The substrate 10 also includes a die pad 11 and a drain terminal 12.

In a semiconductor device according to the present embodiment, a semiconductor chip 40 is mounted on the die pad 11 of the substrate 10. The gate pad 50 and the gate terminal 20 provided on the upper surface of the semiconductor chip 40 are connected to each other via a gate wire 70, and the plurality of source pads 60 are connected to the source terminal 30 via the plurality of source wires 80. The semiconductor chip 40 and the die pad 11 are entirely sealed in the package 100 while the gate terminal 20, the drain terminal 12 and the source terminal 30 are exposed from the package 100.

The substrate 10 is a metal substrate to receive the semiconductor chip 40 on its surface. The substrate 10 includes the die pad 11, which is a region on which the semiconductor chip 40 is mounted, and the drain terminal 12, which extends in one direction from the die pad 11 in a plan view. In the semiconductor device according to the present embodiment, the semiconductor chip 40 having a structure in which a gate and a source are disposed on the upper surface and a drain is disposed on the lower surface, is mounted on the substrate 10. Accordingly, the substrate 10 has the drain terminal 12 extending directly from the die pad 11 and serves to pull out the drain terminal 12 that is electrically connected to the drain on the lower surface of the semiconductor chip 40. The drain terminal 12 may extend in one direction in a plan view and may be bent in upward and downward directions. For example, the drain terminal 12 may be bent upward from downward. The die pad 11 may have any shape or size if the semiconductor chip 40 can be mounted on the surface. The substrate 10 may be also made of a highly conductive metal material and may be, for example, made of copper or a copper alloy.

The gate terminal 20 is electrically connected to the gate pad 50 on the upper surface of the semiconductor chip 40 and serves as a control terminal to allow a voltage to be applied to the gate of the semiconductor chip 40 from the outside of the package 100. The gate pad 50 is electrically connected to the gate terminal 20 via the gate wire 70. The gate terminal 20 has a gate wire connection part 21 in the end region on the side of the die pad 10 in the package 100. The gate wire connection part 21 is a portion to which the gate wire 70 is connected, and is provided in an area close to the die pad 10 in a portion of the gate terminal 20 in the package 100. One end of the gate wire 70 is connected to the gate pad 50 and the other end is connected to the gate wire connection part 21, thereby electrically connecting the gate pad 50 to the gate terminal 20.

The gate terminal 20 is provided apart from the die pad 10 and the drain terminal 12, and is electrically insulated. Moreover, the gate terminal 20 is provided parallel to the drain terminal 12 along the extending direction of the drain terminal 12. The gate terminal 20, like the drain terminal 12, is also formed of a highly conductive metal material. The gate terminal 20 may be made of the same material as the drain terminal 12, and may be made, for example, of copper or a copper alloy.

The source terminal 30 is electrically connected to the plurality of source pads 60 on the upper surface of the semiconductor chip 40, and serves as an external terminal for drawing a source current output from the source of the semiconductor chip 40 to the outside of the package 100. The plurality of source pads 60 is each electrically connected to the source terminal 30 via the plurality of source wires 80. The source terminal 30 also has a source wire connection part 31 in the end region on the side of the die pad 10 in the package 100, as well as the gate terminal 20. The source wire connection part 31 is a portion of the source terminal 30 to which the source wires 80 are connected and is provided in a region close to the die pad 10 in a portion of the package 100. One end of each of the source wires 80 is connected to the source pad 60 and the other is connected to the source wire connection part 31, thereby electrically connecting each source pad 60 to the source terminal 30.

The source terminal 30, as well as the gate terminal 20, is also provided apart from the die pad 10 and the drain terminal 12 and is electrically isolated from the die pad 10 and the drain terminal 12. The source terminal 30 is also provided parallel to the drain terminal 12 along the extending direction of the drain terminal 12. Accordingly, the gate terminal 20 and the source terminal 30 are provided on both sides of the drain terminal 12 so as to interpose the drain terminal 12 between the gate terminal 20 and the source terminal 30. The source terminal 30, as well as the drain terminal 12, is made of a highly conductive metal material. The source terminal 30 may be also made of the same material as the drain terminal 12, and may be made, for example, of copper or a copper alloy. While the plurality of source pads 60 and the plurality of source wires 80 are provided, only a single source terminal 30 serving as an external terminal of the semiconductor device is provided.

The gate terminal 20 and the source terminal 30 may be arranged in various ways on both sides of the drain terminal 12 as long as the gate terminal 20 and the source terminal 30 extend in one direction parallel to the drain terminal. However, the gate terminal 20 and the source terminal 30 are preferably provided such that the distance between the gate terminal 20 and the drain terminal 12 is equal to the distance between the source terminal 30 and the drain terminal 12. This is because the scope of the application of the semiconductor device is more expanded by forming the semiconductor device into a shape complying with general standards.

The semiconductor chip 40 is a semiconductor device that serves as a switching device and may be configured, for example, as a DMOSFET (Double-Diffused Metal Oxide Semiconductor Field Effect Transistor). The semiconductor chip 40 has a structure in which a gate and a source are formed on an upper surface and a drain is disposed on a lower surface.

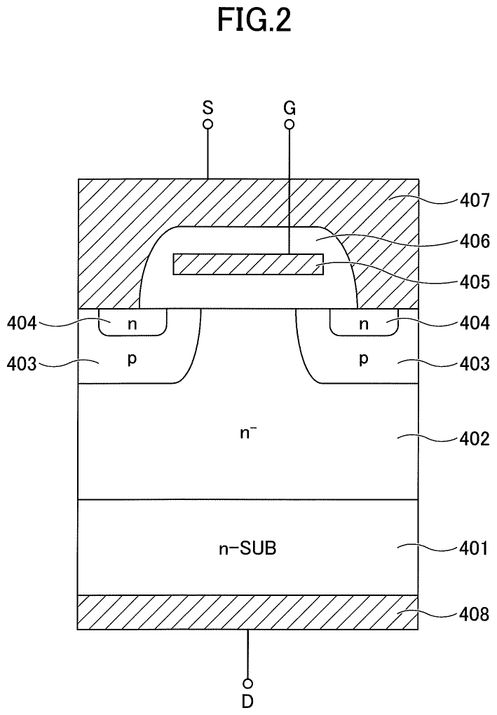

FIG. 2 is a cross-sectional view illustrating an example of a configuration of a semiconductor chip 40 of a semiconductor device according to the present embodiment. As illustrated in FIG. 2, a drift layer 402 is formed on an n-type semiconductor substrate 401. Body regions 403 having a p-type conductive type are formed in upper portions of the drift layer 402, and source regions 404 having an n-type conductive type are formed in upper portions in the p-type body regions 403. Also, a gate insulating film 406 is formed over the source regions 404, the body regions 403, and the drift layer 402 so as to straddle the source regions 404 on both sides, and a gate electrode 405 is provided in the gate insulating film 406. A metal layer 407 is also formed over the source region 404 and the gate insulating film 406. The metal layer 407 forms the source pad 60 described in FIG. 1 on the upper surface of the semiconductor chip 40. Also, a metal pad electrically connected to the gate electrode 405 and provided on the upper surface of semiconductor chip 40 forms the gate pad 50 in FIG. 1. Also, a metal layer 408 is formed on the back surface of the n-type semiconductor substrate 401, bonded to the die pad 11 illustrated in FIG. 1 with solder or the like, and electrically connected to the drain terminal 12.

The n-type semiconductor substrate 401 may be made of a variety of semiconductor materials, but may be made of a wide gap semiconductor material such as silicon carbide (SiC) and gallium nitride (GaN). Similarly, the drift layer 402 may be made of a variety of semiconductor materials, but may be made of a wide gap semiconductor material such as silicon carbide (SiC) and gallium nitride (GaN). By using a wide gap semiconductor material, a low-loss and high-voltage-resistant semiconductor device can be formed.

The drift layer 402 formed on the n-type semiconductor substrate 401 may be formed, for example, by epitaxial growth. The body regions 403 and the source regions 404 may be formed, for example, by general ion implantation. The gate insulating film 406 may be also provided by forming a silicon oxide film (SiO2), for example, by thermal oxidation. For example, a polysilicon that is enhanced in conductivity by impurity diffusion may be used as the gate electrode 405. A metallic material for wiring such as aluminum and copper may be used as the metal layers 407, 408.

Thus, the semiconductor chip 40 may be made of a material containing a wide gap semiconductor, such as silicon carbide (SiC) and gallium nitride (GaN). That is, the semiconductor chip 40 may be a wide gap semiconductor chip. In this manner, a low-loss and high-voltage-resistant MOS transistor can be formed.

FIG. 1 is described again. As illustrated in FIG. 1, the semiconductor chip 40 of the semiconductor device according to the present embodiment has a rectangular shape. The semiconductor chip 40 has short sides 41a, 41b and long sides 42a, 42b that are opposite to each other. The short side 41a is disposed on the gate terminal 20 side, and the short side 41b is disposed on the source terminal 30 side. The short sides 41a, 41b are arranged parallel to the extending direction of the gate terminal 20, the drain terminal 12, and the source terminal 30. The gate terminal 20, the drain terminal 12, and the source terminal 30 are positioned only on the long side 42a of the semiconductor chip 40, and only the die pad 11 is present close to the long side 42b.

The gate pad 50 extending parallel to the short side 41a is disposed near the short side 41a on the gate terminal 20 side on the upper surface of the semiconductor chip 40. In addition, the plurality of source pads 60 is arranged parallel to the short side 41b while being arranged from a position near the short side 41b on the upper surface of the semiconductor chip 40 toward the short side 41a on the opposite side. In FIG. 1, the number of source pads 60 is four, but this is only an example. The number of source pads 60 may be more than or less than four, as long as the number is more than one. Also, although the gate pad 50 extends parallel to the short side 41a, the shape of the gate pad 50 does not need to have an oblong shape. The gate pad 50 may be, for example, square.

By forming the semiconductor chip 40 into a rectangular shape, and arranging the long sides 42a, 42b of the semiconductor chip 40 so as to extend while straddling or crossing the gate terminal 20 and the source terminal 30, the source pads 60 can approach the source wire connection part 31 of the source terminal 30 without arranging the gate terminal 20 too far from the gate terminal. That is, by arranging the short sides 41a, 41b of the semiconductor chip 40 so as to be parallel to the extending direction of the gate terminal 20 and the source terminal 30, and by arranging the long sides 42a, 42b of the semiconductor chip 40 so as to extend between the gate terminal 20 and the source terminal 30, the distance between the source pads 60 and the source wire connection part 31 of the source terminal 30 can be shortened.

In FIG. 1, the semiconductor chip 40 is disposed such that the center of gravity 43 of the semiconductor chip 40 is closer to the source wire connection part 31 of the source terminal 30 than the gate wire connection part 21 of the gate terminal 20. That is, instead of disposing the semiconductor chip 40 so that the center of gravity 43 of the semiconductor chip 40 coincides with the center of the drain terminal 12, the semiconductor chip 40 is disposed close to the source terminal 30. Thus, the semiconductor device can be configured such that the distance between the short side 41b of the semiconductor chip 40 on the source terminal 30 side and the source wire connection part 31 of the source terminal 30 is shorter than the distance between the short side 41a on the gate terminal 20 side and the gate wire connection part 21 of the gate terminal 20 in the direction in which the gate terminal 20, the drain terminal 12, and the source terminal 30 are arrayed in the package 100. Such an arrangement can shorten the source wires 80 that connect the source pads 60 to the source wire connection part 31 of the source terminal 30 and reduce the inductance of the source wires 80. Thus, the back electromotive force of the gate-to-source voltage (because the source is grounded, hereinafter referred to as a “gate voltage”) when the semiconductor device operates as a switch can be reduced, and the switching operation can be made faster.

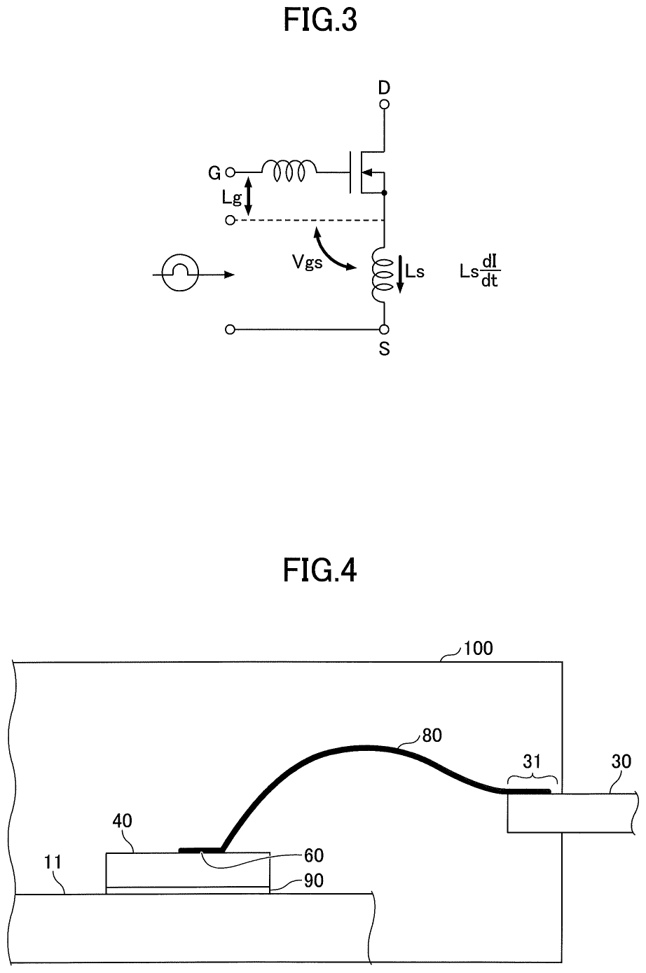

FIG. 3 is a diagram for explaining generated back electromotive force when a MOS transistor performs a switching operation. In FIG. 3, a circuit diagram of an n-type MOS transistor is illustrated, while expressing inductance of the gate wire 50 as Lg, and expressing inductance of the source wire 60 as Ls. When the gate voltage is made Vgs, which is the voltage drop of the inductance Lg of the gate wire 50, the gate voltage is expressed as Vgs−Ls (dI/dt).

When a positive voltage is applied to the gate and the MOS transistor turns on, the (dI/dt) becomes positive, and the gate voltage applied to the MOS transistor decreases compared to the output of the gate driver, which decreases the turn-on rate. In the meantime, when the MOS transistor is turned off, the (dI/dt) becomes negative, which increases the output of the gate driver and also decreases the turn-off rate.

Thus, because the MOS transistor is turned on and off, the back electromotive force (−L(dI/dt)) is generated, by reducing the inductance Ls of the source wire 60, the back electromotive force (−L(dI/dt)) can be reduced. Thus, the switching operation of the MOS transistor can be made faster.

FIG. 1 is described again. In the semiconductor device according to the present embodiment, the center of gravity 43 of the semiconductor chip 40 having a rectangular shape is arranged close to the source terminal 30 side, thereby reducing the inductance Ls of the source wires 60. Thus, the switching rate of the semiconductor device can be increased.

In FIG. 1, at least two of the multiple source wires 80 at the right end are configured to be shorter than the gate wire 70. Thus, the inductance Ls of the source wires 80 can be reduced, and the switching rate can be improved by making the at least one, preferably more than one, source wire 80 shorter than the gate wire 70.

Although the gate wire 70 also has the inductance Lg, the source current is much greater than the gate current and has a difference of more than 10 times. Also, because there are more than one source wires 80 relative to a single gate wire 70, reducing the inductance Ls of the source wire 80 should be prioritized to satisfy the intention of implementing the faster switching operation.

Hence, the semiconductor chip 40 may be disposed much closer to the source terminal 30 than the semiconductor chip 40 in FIG. 1, and for example, the leftmost source pad 60 may be configured to coincide with the center of the drain terminal 12. How close the semiconductor chip 40 is disposed to the source terminal 30 can be arranged in a variety of configurations, while considering the size of the semiconductor chip 40 and the die pad 11, and a balance between the distance and the length of the gate wire 70 and the like.

The ratio of the length of the semiconductor chip 40 between the long sides 42a, 42b and the short sides 41a, 41b may be also determined appropriately depending on the intended use, but may be, for example, a rectangle that satisfies the long sides/short sides ≥1.6. When the semiconductor chip 40 has a shape similar to a square, the semiconductor chip 40 cannot take a configuration that shortens the source wires 80 without lengthening the gate wire 70 too much. Accordingly, the semiconductor chip 40 is preferably a rectangle that satisfies the long sides/short sides ≥1.6.

A wiring metal material such as aluminum and copper may be uses as the gate pad 50 and the source pad 60 depending on the intended use, as described above.

The gate wire 70 and the source wire 80 may be gold, aluminum and the like, although aluminum may be used in terms of cost and the like. When an aluminum wire is bonded, the aluminum wire is bonded in a state of slightly extending along the lengthwise direction of the pad, but when each of the lengths of the gate wire 70 and the source wires 80 is considered, only a wire portion that is not bonded to the gate pad 50 or the source pad 60 is regarded as the length of the wire.

All of the die pad 11 and the semiconductor chip 40, and root portions of gate terminal 20, the drain terminal 12 and the source terminal 30 are sealed in the package 100, and the sealing resin can be selected from appropriate resin depending on the intended use.

In FIG. 1, the gate terminal 20, the drain terminal 12 and the source terminal 30 are also packaged as a 3-pin type in which the gate terminal 20, the drain terminal 12 and the source terminal 30 extend like pins outside the package 100, but the shape of the gate terminal 20, the drain terminal 12 and the source terminal 30 may have various configurations depending on the intended use.

FIG. 4 is a cross-sectional view illustrating an example of a connection state between the source terminal 30 and the source pad 60 of the semiconductor device according to the present embodiment. As illustrated in FIG. 4, the semiconductor chip 40 is bonded to the die pad 11 with solder 90. The source terminal 30 is located higher than the semiconductor chip 40, and is connected to the source pad 60 and the source wire connection part 31 of the source terminal 30 via the source wires 80. The die pad 11, the semiconductor chip 40, the source wire connection part 31 and the source wires 80 are then sealed in the package 100. The drain terminal 12 and the gate terminal 20 may be also located at the same height as the source terminal 30.

As illustrated in FIG. 4, because the source wire 80 is used with some margin, the length also becomes longer than the distance between the source pad 60 and the source terminal 30. Hence, forming the semiconductor chip 40 in a rectangle, bringing the center of gravity 43 close to the source terminal 30, and shortening the source wires 80 to reduce the inductance Ls greatly contribute to faster switching.

The semiconductor device chips that have been conventionally used have a square or slightly longitudinal shape and are symmetrically arranged so that the center of gravity coincides with the center of the drain terminal. Hence, the lengths of the source wires that connect the source pads to the source terminal have been long. Such a configuration cannot sufficiently reduce the inductance Ls of the source wires, and back electromotive force prevents faster switching.

In contrast, according to the semiconductor device of the present embodiment, as illustrated in FIG. 1, the source wires 80 can be shortened, and the inductance Ls of the source wires 80 can be reduced, thereby speeding up the switching.

It should be understood that the embodiments disclosed herein are exemplary in all respects and are not limited in any respect. The present invention is not limited to these examples, and is intended to include all modifications within the meaning and scope of the claims and equivalents to those of the claims.

### DESCRIPTION OF THE REFERENCE NUMERALS

10 substrate
11 die pad
12 drain terminal
20 gate terminal
21 gate wire connection part
30 source terminal
31 source wire connection part
40 semiconductor chip
41a, 41b short sides
42a, 42b long sides
43 gravity point
50 gate pad
60 source pad
70 gate wire
80 source wire
90 solder
100 package
401 n-type semiconductor substrate
402 drift layer
403 body layer
404 source region
405 gate electrode
406 gate insulating film
407, 408 metal layer

1. A packaged semiconductor device, comprising:
a substrate including a die pad and a drain terminal, the drain terminal extending from the die pad in one direction in a plan view;
a gate terminal and a source terminal extending in the one direction on both sides of the drain terminal;
a semiconductor chip having a rectangular shape and disposed on the die pad such that short sides are parallel to the drain terminal and a center of gravity is closer to the source terminal than the gate terminal;
a gate pad disposed on the gate terminal side on an upper surface of the semiconductor chip;
a plurality of source pads arrayed from the source terminal side toward the gate terminal side on the upper surface of the semiconductor chip;
a gate wire connecting the gate pad to the gate terminal; and
a plurality of source wires connecting the plurality of source pads to the source terminal.

2. The packaged semiconductor device as claimed in claim 1, wherein at least one of the plurality of source wires is shorter than the gate wire.

3. The packaged semiconductor device as claimed in claim 2, wherein the two or more of the plurality of source wires are shorter than the gate wire.

4. The packaged semiconductor device as claimed in claim 1, wherein the semiconductor chip is a wide gap semiconductor chip.

5. The packaged semiconductor device as claimed in claim 2, wherein the semiconductor chip is a wide gap semiconductor chip.

6. The packaged semiconductor device as claimed in claim 3, wherein the semiconductor chip is a wide gap semiconductor chip.
